(19) United States
(12) Patent Application Publication
(10) Pub. No.: US 2026/0353589 A1
(43) Pub. Date: Nov. 5, 2026

(54) CHASSIS DEVICE FOR SERVER ROOM

(71) Applicant: Delta Electronics, Inc., Taoyuan City (TW)

(72) Inventors: Yu-Fan Yang, Taoyuan City (TW); Hung-Min Cho, Taoyuan City (TW); Mu-Bo Chang, Taoyuan City (TW); Shan-Chun Yang, Taoyuan City (TW)

(21) Appl. No.: 19/654,697

(22) Filed: Apr. 22, 2026

Related U.S. Application Data
(60) Provisional application No. 63/800,108, filed on May 5, 2025.

(30) Foreign Application Priority Data
Sep. 19, 2025 (TW) 114135999

(51) Int. Cl. H05K 7/14

(52) U.S. Cl. CPC H05K 7/1489; H05K 7/1415

(57) ABSTRACT

A chassis device for a server room is disclosed and includes an accommodation space, a positioning roller, a chassis unit, a handle component and a latching component. The chassis unit includes a slide rail structure arranged at the bottom and top of the chassis unit, and allowing the chassis unit to be placed into or moved out of the accommodation space through the opening along a first direction. The handle component is pivotally arranged at the front end, and includes a hook structure spatially corresponding to the positioning roller with an axis parallel to a second direction and the slide rail structure. The slide rail structure aligns with the positioning roller to allow the chassis unit to slide into the accommodation space. When the handle component is swung to engage the hook structure with the positioning roller, the latching component is enabled to limit the handle component.

### CROSS-REFERENCE TO RELATED APPLICATION

This application claims the benefit of U.S. Provisional Application No. 63/800,108 filed on May 05, 2025, and entitled “MODULARIZED QUICK-LOCK HANDLE”. This application claims priority to Taiwan Patent Application No. 114135999, filed on Sep. 19, 2025. The entireties of the above-mentioned patent applications are incorporated herein by reference for all purposes.

### FIELD OF THE INVENTION

The present disclosure relates to a chassis structure, and more particularly to a chassis device for a server room, which enables a latching component through a handle component, so that a chassis unit is fixed in an accommodation space at the same time, to avoid the risk of the chassis unit being separated from the system due to accidental human touch.

### BACKGROUND OF THE INVENTION

With the vigorous development of data centers and server rooms, the types of related chassis products are becoming more and more diverse. In order to facilitate installation, maintenance, and expansion, most chassis used in the server rooms are becoming modular and hot-swappable. For example, in a cooling system of the server room, the water pump is a key component that influences the cooling capacity, the power consumption and the component selection. Moreover, the water pump is also the source of driving fluid flow. In a standard product, the chassis unit that includes the hot-swappable water pump module is inherently heavy, so that a significant force is required to insert into the system or remove from the system. On the other hand, the hot-swappable chassis unit requires a locking mechanism to avoid the risk of the chassis unit being accidentally disconnected from the system. Furthermore, an improperly designed locking mechanism can damage the insertion and removal handle or render it impossible to replace.

Therefore, there is a need of providing a chassis device for a server room, which enables a latching component through a handle component, so that a chassis unit is fixed in an accommodation space at the same time, to avoid the risk of the chassis unit being separated from the system due to accidental human touch, and obviate the drawbacks encountered from the prior arts.

### SUMMARY OF THE INVENTION

It is an object of the present disclosure to provide a chassis device for a server room. By arranging a latching component on the swing path of a handle component, when the hook structure of the handle component is cooperated with a slide rail structure to engage with a positioning roller, latching component is simultaneously activated by the handle component to limit the handle component at a fixed position, thereby fixing the chassis unit in an accommodation space, avoiding the risk of the chassis unit being separated from the system due to accidental human touch.

It is another object of the present disclosure to provide a chassis device for a server room. Bearing balls are used to construct sliding components between the bottom of the accommodation space and the chassis unit to provide sufficient support and achieve labor-saving functions. In addition, the positioning roller includes the roller disposed on the top and bottom of the accommodation space and cooperated with a guiding groove disposed in the chassis unit to achieve both labor-saving and position-limiting functions. It allows the chassis unit being smoothly inserted into or removed from the accommodation space on the chassis device to avoid the collision damage or the scratches on the inner wall of the accommodation space. Notably, the handle component is pivotally connected to the front end of the chassis unit and further cooperated with the positioning component when the chassis unit is placed or moved out of the accommodation space. By meshing the arc-shaped engagement groove with the positioning component located in the guiding groove, the handle component is driven to fold or unfold the holding portion. It is convenient for users to operate and achieves labor-saving performance. Furthermore, a latching component with an inclined surface is arranged on the swing path of the handle component when it is folded or unfolded. The direction in which the handle component swings left and right is perpendicular to the direction in which the latching component stretches up and down. When the user operates the handle component to place the chassis unit into the accommodation space, the arc-shaped engagement groove and the positioning roller are engaged with each other to drive the handle component to swing. The handle component is swung first to push against the lower part of the inclined surface, and then the latching component is pressed out of the swing path of the handle component. When the chassis unit is completely accommodated in the accommodation space, the handle component is folded at a fixed position and the latching component is released, so that the latching component is reset to the swing path of the handle component, the swing of the latching component is limited, and the locking purpose is achieved. On the other hand, when the user wants to operate the handle component to move the chassis unit out of the accommodation space, the user can use one hand to move the latching component adjacent to the handle component, so that the latching component is pressed out of the swing path of the handle component. Then, the handle component is allowed to swing to the unfold position, thereby moving the chassis unit out of the accommodation space. Thereby, it allows the users to easily install or remove the chassis unit, and the entire process is smooth and effortless. Furthermore, without moving the latching component by hand, the handle component is swung and folded to activate the latching component, so that the handle component is limited to the folded position, thereby fixing the chassis unit in the accommodation space, avoiding the risk of the chassis unit being separated from the system due to accidental human touch.

In accordance with an aspect of the present disclosure, a chassis device is provided and includes an accommodation space, a positioning roller, a chassis unit, a handle component and a latching component. The accommodation space includes an opening, wherein the opening faces a first direction. The positioning roller is disposed on a bottom and/or a top of the accommodation space, arranged adjacent to the opening, and has an axis parallel to a second direction. The chassis unit includes a slide rail structure disposed on a bottom or/and a top of the chassis unit, wherein the slide rail structure is spatially corresponding to the positioning roller, allowing the chassis unit to be placed into or moved out of the accommodation space along the first direction through the opening. The handle component is pivotally mounted on a front end of the chassis unit and includes a hook structure spatially corresponding to the positioning roller and the slide rail structure, wherein the handle component is allowed to swing in a third direction relative to the front end, and the first direction, the second direction and the third direction are perpendicular to each other. The latching component is disposed on the front end of the chassis unit and spatially corresponding to the handle component, wherein the slide rail structure is aligned with the positioning roller to allow the chassis unit to slide into the accommodation space, wherein when the handle component is swung along the third direction and the hook structure is engaged with the positioning roller, the latching component is activated to limit the handle component from swinging.

In an embodiment, the handle component further includes a holding portion and a connection rod, the hook structure and the holding portion are respectively located at two opposite ends of the connection rod, the holding portion protrudes outwardly from the front end, and the connection rod is pivotally connected to the chassis unit, wherein the handle component is swung to a first position, the chassis unit allows displacement along the first direction, and the hook structure allows engagement with the positioning roller to drive the handle component to swing to a second position.

In an embodiment, the chassis unit includes a window disposed on the front end of the chassis unit and extended along the third direction, and the connection rod passes through the window, wherein when the handle component is swung between the first position and the second position, the connection rod is swung between two opposite ends of the window.

In an embodiment, the latching component includes a fixing bracket, an elastic element and a latch element, the fixing bracket is disposed on the front end of the chassis unit and arranged adjacent to the holding portion unfolded at the second position, and the latch element is connected to the fixing bracket through the elastic element, wherein the latch element is allowed to protrude into the window, wherein when the latch element protrudes into the window, the handle component is locked at the second position.

In an embodiment, the latch element further includes an inclined surface, and a height of inclined surface is increased from the first position to the second position, wherein when the holding portion is subjected to force to swing the handle component from the first position to the second position, the connection rod pushes against the elastic element through the inclined surface, so that the latch element is driven to disengage from the window, wherein when the handle component is swung to the second position, the connection rod is disengaged from the inclined surface to release the elastic element, and the latch element protrudes to the window to lock the handle component at the second position, wherein the latch element is subjected to force to push against the elastic element and drive the latch element to disengage from the window, the handle component is allowed to swing from the second position to the first position under the force of the holding portion.

In an embodiment, the inclined surface has an inclination angle ranged from 10 degrees to 45 degrees.

In an embodiment, the latch element further includes a pressing plate protruding from the front end of the chassis unit and configured to receive force to drive the latch element to press against the elastic element and disengage the latch element from the window.

In an embodiment, the pressing plate is separated from the holding portion folded at the second position to form an operating distance, and the operating distance is ranged from 3 cm to 6 cm, so that a user is allowed to simultaneously hold the holding portion and move the pressing plate with one hand.

In an embodiment, the latch element is constantly pressed by the elastic element to protrude into the window, wherein when the latch element is forced by the pressing plate to press against the elastic element and disengage from the window to maintain a misalignment with the connection rod, the handle component is allowed to swing between the first position and the second position.

In an embodiment, the hook structure includes an arc-shaped engagement groove for being aligned with the slide rail structure and the positioning roller, and the arc-shaped engagement groove is allowed engaging the positioning roller and driving the handle component to swing to the second position.

In an embodiment, when the handle component is swung to the second position, the positioning roller is limited to a tail end of the slide rail structure and engaged with a tail end of the arc-shaped engagement groove, the chassis unit is locked in the accommodation space, the holding portion is retracted to the front end of the chassis unit, and the holding portion is locked at the second position through the latching component.

In an embodiment, when the holding portion is forced to protrude from the front end and drive the handle component to swing from the second position to the first position, the positioning roller is limited to the slide rail structure and an opening end of the arc-shaped engagement groove, and the chassis unit allows being moved out of the accommodation space through the opening.

In an embodiment, when a tail end of the slide rail structure is close to the positioning roller, the handle component is engaged with the positioning roller through the arc-shaped engagement groove, and the handle component is driven to rotate to the second position.

In an embodiment, the arc-shaped engagement groove has a width greater than a diameter of the positioning roller, and is tapered from an opening end to a tail end, and the arc-shaped engagement groove further comprises a clamping point disposed on the tail end of the arc-shaped engagement groove, wherein when the chassis unit is completely accommodated in the accommodation space, the clamping point is engaged with the positioning roller.

In an embodiment, when the handle component is swung, the arc-shaped engagement groove and the slide rail structure are at least partially intersected.

In an embodiment, the hook structure is received within the chassis unit, the connection rod is connected between the hook structure and the holding portion, and protrudes from the front end of the chassis unit through the window, and the holding portion is located outside the front end of the chassis unit.

In an embodiment, the slide rail structure is in communication along the first direction from a rear end of the chassis unit toward the front end, wherein when a rear end of the chassis unit is placed into the accommodation space through the opening, the handle component is pre-rotated to the first position, and the positioning roller allows being aligned to a tail end of the slide rail structure.

In an embodiment, the handle component is disposed on the chassis unit through a pivot component, and the pivot component is located between a tail end of the slide rail structure and the front end of the chassis unit.

In an embodiment, the chassis unit is a water pump module and includes a quick-connect joint arranged at a rear end of the chassis unit, wherein when the chassis unit is completely accommodated in the accommodation space, the quick-connect joint is connected to a server water cooling system.

In an embodiment, the chassis unit further includes a sliding component, and the sliding component is arranged at a bottom of the chassis unit along the first direction, wherein the sliding component allows the chassis unit to slide relative to the accommodation space along the first direction therethrough and supports the chassis unit.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a schematic structural view illustrating a chassis device for a server room according to an embodiment of the present disclosure and taken from an upper perspective;

FIG. 2 is a schematic structural view illustrating the chassis device for the server room according to the embodiment of the present disclosure and taken from a lower perspective;

FIG. 3 is a lateral view illustrating the chassis device having the chassis unit being placed into or moved out of the accommodation space according to the first embodiment of the present disclosure;

FIG. 4 is a rear view illustrating the chassis device having the chassis unit being placed into or moved out of the accommodation space according to the first embodiment of the present disclosure;

FIG. 5 is an enlarged view of region P1 in FIG. 4;

FIG. 6 is an enlarged view of region P2 in FIG. 4;

FIG. 7 is a schematic diagram showing the handle component rotated to the first position;

FIG. 8 is a schematic diagram showing a transition state of the handle component being swung from the first position to the second position;

FIG. 9 is a schematic diagram showing the handle component rotated to the second position;

FIGS. 10 and 11 are schematic diagrams illustrating the latching component in a protruding state under the action of an elastic force;

FIGS. 12, and 13 are schematic diagrams illustrating the latching component in a retracted state under the action of a force resisting the elastic force;

FIG. 14 is a front view illustrating the handle component swung to the first position;

FIG. 15 is a front view illustrating a transition state of the handle component being swung from the first position to the second position;

FIG. 16 is a front view illustrating the handle component swung to the second position;

FIG. 17 is a front view illustrating the handle component swung to the second position and the latching component unlocked;

FIG. 18 is a front view illustrating a transition state of the handle component being swung from the second position to the first position; and

FIG. 19 is a front view illustrating the handle component swung to the first position.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “front,” “rear,” “left,” “right,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the "first," "second" and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, "and / or" and the like may be used herein for including any or all combinations of one or more of the associated listed items.

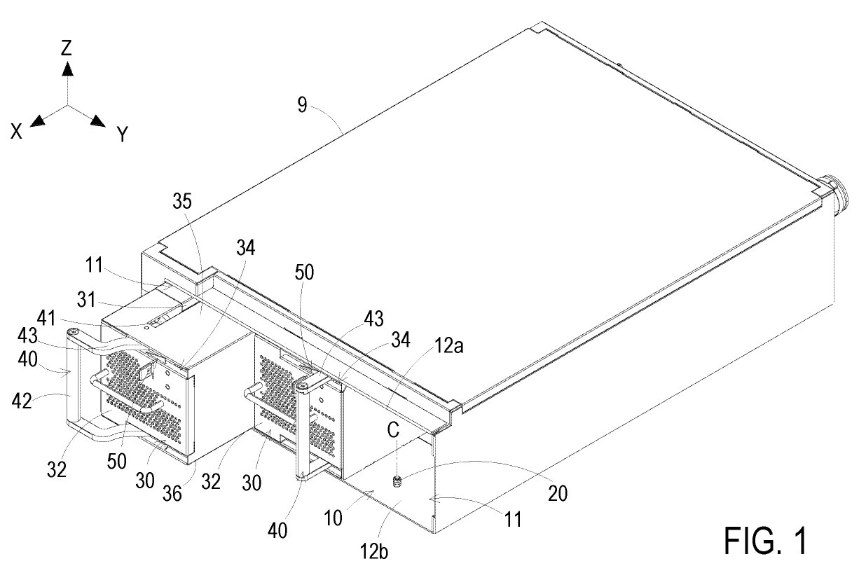

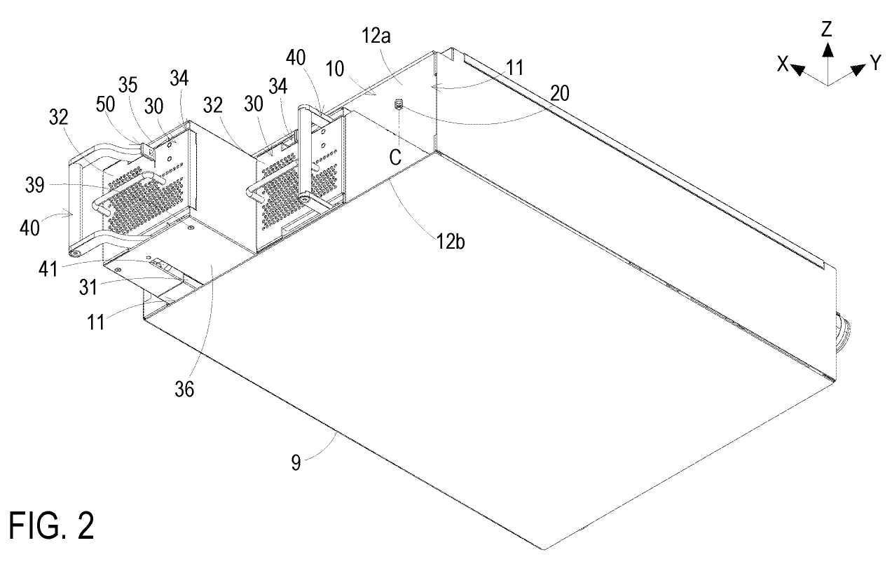

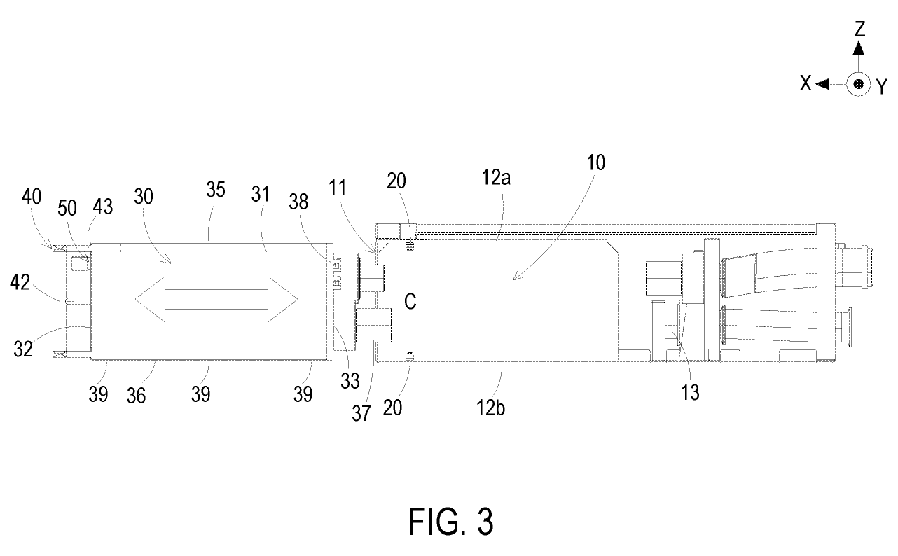

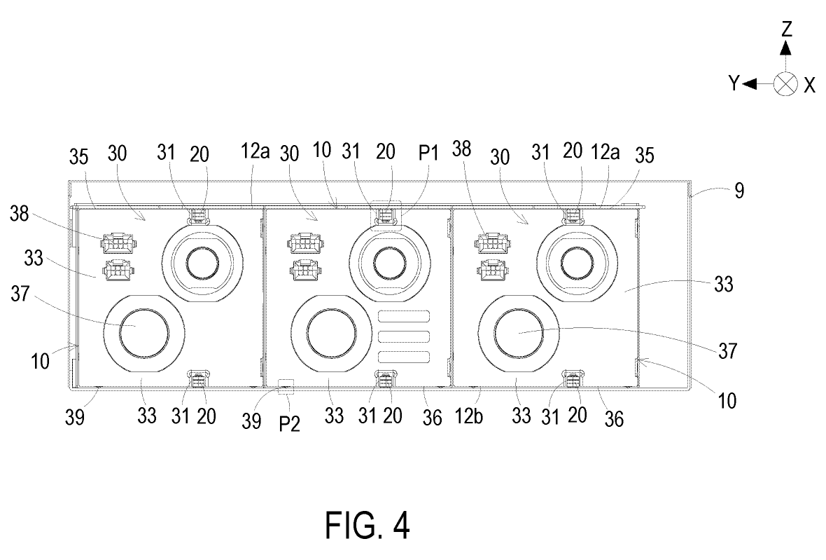

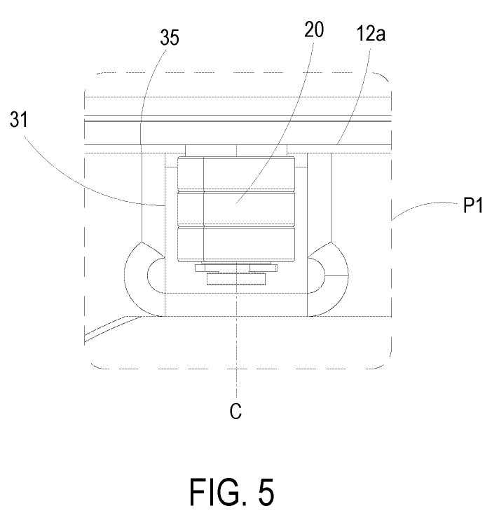

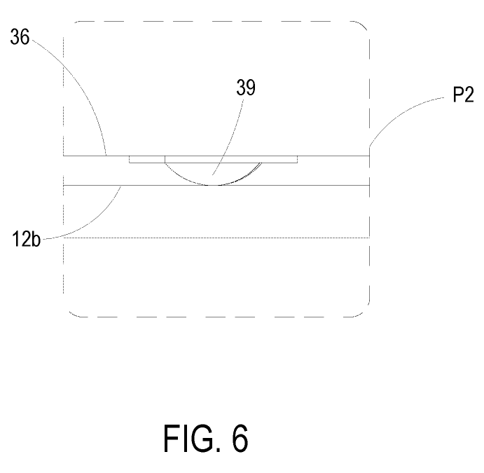

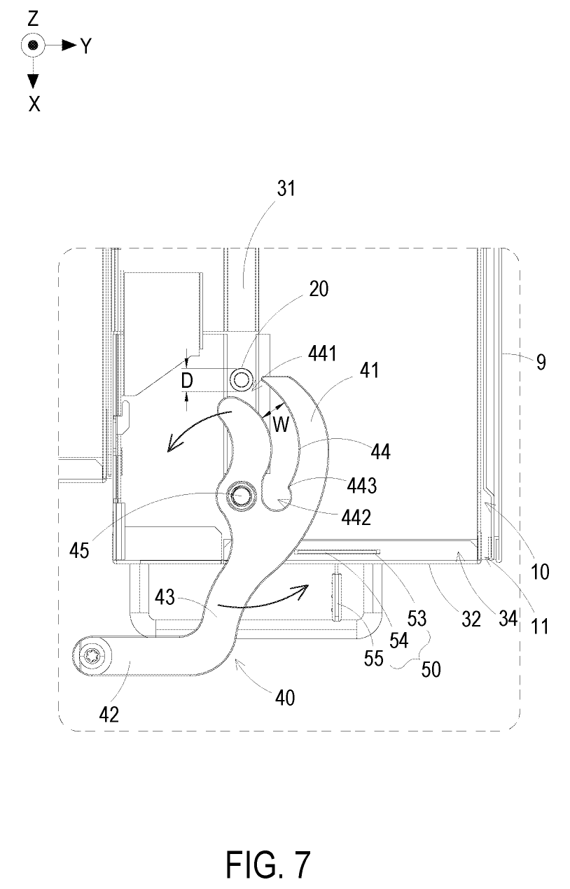

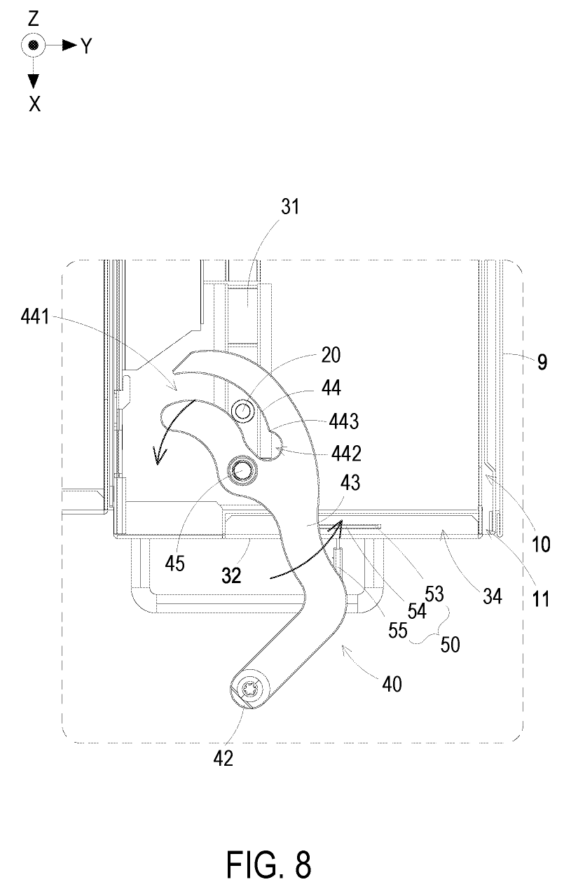

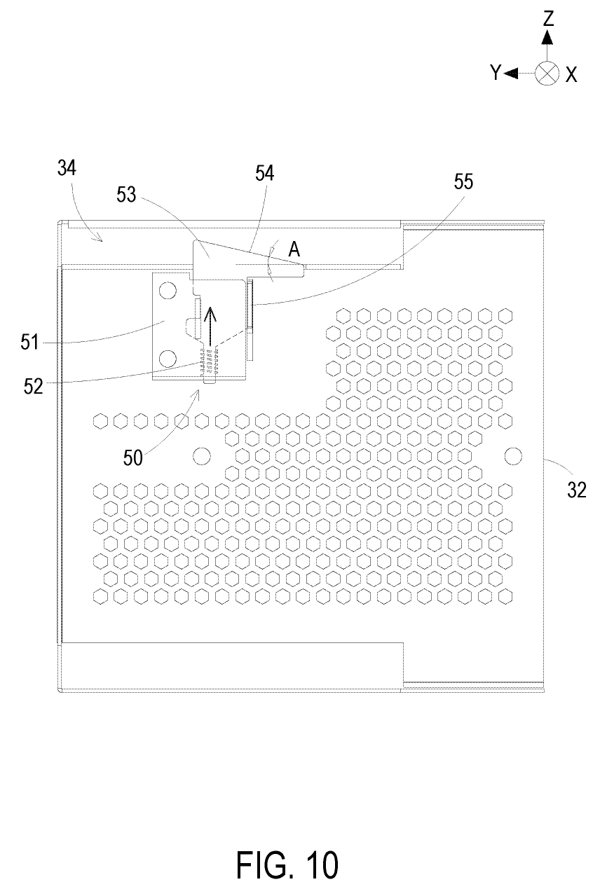

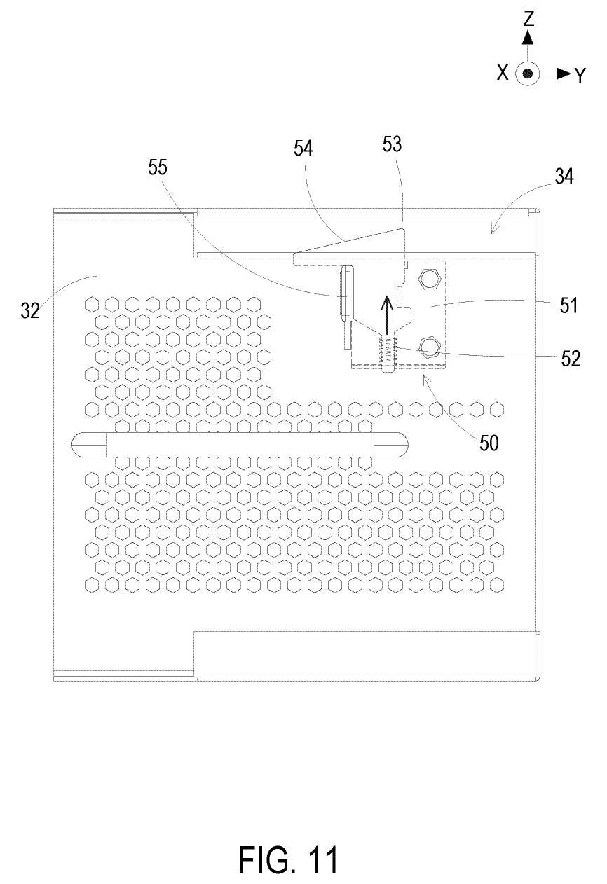

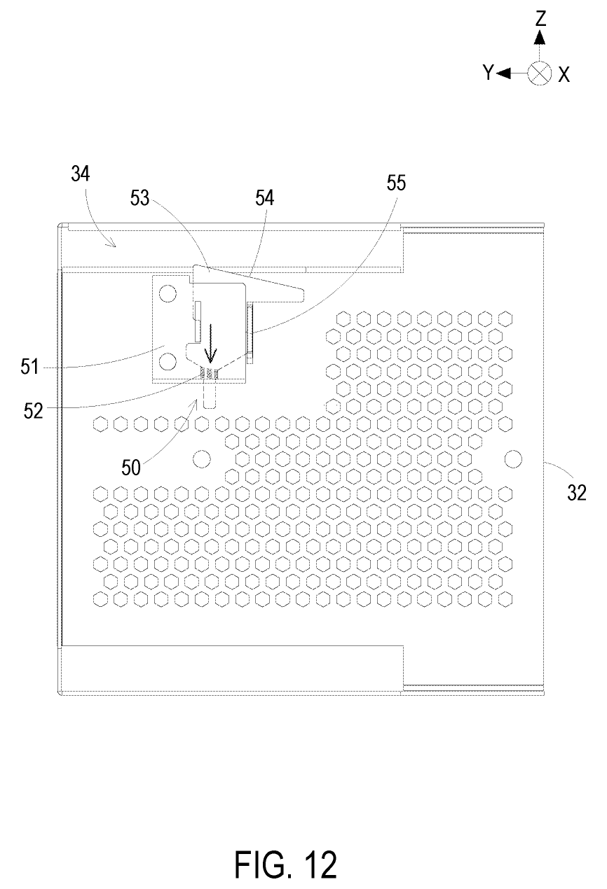

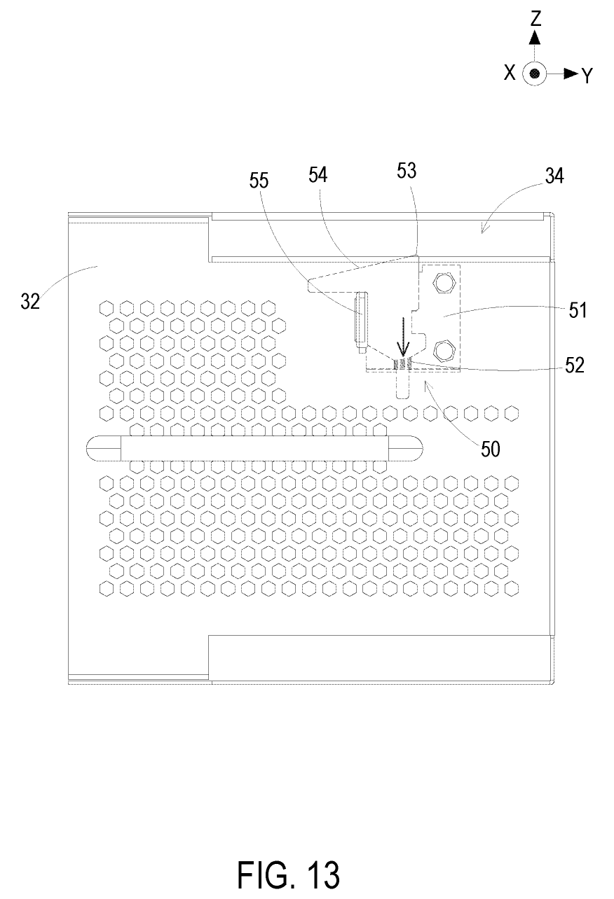

FIGS. 1 and 2 are schematic structural views illustrating a chassis device for a server room according to an embodiment of the present disclosure. FIGS. 3 and 4 are a lateral view and a rear view illustrating the chassis device having the chassis unit being placed into or moved out of the accommodation space according to the first embodiment of the present disclosure, respectively. FIGS. 5 and 6 are enlarged views of region P1 and region P2 in FIG. 4. FIGS. 7, 8, and 9 are schematic diagrams showing the handle component rotated to the first position, a transition state and the second position, respectively. FIGS. 10 and 11 are schematic diagrams illustrating the latching component in a protruding state under the action of an elastic force. FIGS. 12 and 13 are schematic diagrams illustrating the latching component in a retracted state under the action of a force resisting the elastic force. Please refer to FIGS. 1-13 . The present disclosure provides a chassis device 9 for a server room. The chassis device 9 includes an accommodation space 10, a positioning roller 20, a chassis unit 30, a handle component 40 and a latching component 50. As shown in FIGS. 1, 2, and 4 the chassis device 9 includes a plurality of accommodation spaces 10 with the same structure arranged in a single row or a multi-row array, and each accommodation space 10 allows one chassis unit 30 to be installed therein. Moreover, the installation and removal of each chassis unit 30 are independent and do not interfere with each other. In the following descriptions only one accommodation space 10 of the chassis device 9 paired with one single chassis unit 30 is taken as an example. The present disclosure is not limited thereto. In the embodiment, the accommodation space 10 includes an opening 11. The opening 11 faces a first direction (i.e., parallel to the X axial direction), as shown in FIG. 3. The positioning roller 20 is disposed on a bottom 12b and/or a top 12a of the accommodation space 10, arranged adjacent to the opening 11, and has an axis C parallel to a second direction (i.e., parallel to the Z axial direction). As shown in FIG. 4, the chassis unit 30 includes a slide rail structure 31 and sliding component 39. The slid rail structure 31 is disposed on a bottom 36 or/and a top 35 of the chassis unit 30, spatially corresponding to the positioning roller 20, and allows the chassis unit 30 to be placed into or moved out of the accommodation space 10 along the first direction (i.e., parallel to the X axial direction) through the opening 11. Preferably but not exclusively, the sliding component 39 includes a plurality of bearing balls, which are disposed on the bottom 36 of the chassis unit 30 along the first direction (i.e., parallel to the X axial direction). The sliding component 39 allows the chassis unit 30 to slide relative to the accommodation space 10 along the first direction (i.e., parallel to the X axial direction), and supports the chassis unit 30. The handle component 40 is pivotally mounted on a front end 32 of the chassis unit 30 and includes a hook structure 41. The hook structure 41 is spatially corresponding to the positioning roller 20 and the slide rail structure 31. In the embodiment, the handle component 40 is allowed to swing left and right in a third direction (i.e., parallel to the Y axial direction) relative to the front end 32, and the first direction, the second direction and the third direction are perpendicular to each other. In the embodiment, the latching component 50 is disposed on the front end 32 of the chassis unit 30 and spatially corresponding to the handle component 40. As show in FIGS. 3 and 4, the slide rail structure 31 is aligned with the positioning roller 20 to allow the chassis unit 30 to slide into the accommodation space 10. Moreover, when the handle component 40 is swung along the third direction (i.e., parallel to the Y axial direction), and the hook structure 41 is engaged with the positioning roller 20 (as shown in FIG. 8), the latching component 50 is activated to limit the handle component 40 from swinging. The detailed operation description is as follows.

In the embodiment, the sliding component 39 includes a plurality of bearing balls, as shown in FIGS. 3 and 4. The plurality of bearing balls are arranged on the bottom 36 of the chassis unit 30 along the first direction (i.e., parallel to the X axial direction), and spatially corresponding to the bottom 12b of the accommodation space 10. Preferably but not exclusively, the plurality of bearing balls are arranged in pairs and disposed on the bottom 36 of two opposite sides of the slide rail structure 31. For example, the plurality of bearing balls are arranged symmetrically at the left side and the right side of the slide rail structure 31. Certainly, the present disclosure is not limited thereto. In the embodiment, when the chassis unit 30 is inserted into or removed from the accommodation space 10 through the opening 11 along the first direction (i.e., parallel to the X axial direction), the sliding component 39 abuts the bottom 12b of the accommodation space 10 to support the chassis unit 30. In this way, the contact area between the chassis unit 30 and the accommodation space 10 is reduced, and the displacement of the chassis unit 30 relative to the accommodation space 10 is optimized. Certainly, the present disclosure is not limited thereto.

In the embodiment, when the slide rail structure 31 on the top 35 and the bottom 36 of the chassis unit 30 have the open ends aligned with the positioning roller 20 as shown in FIG. 4, the chassis unit 30 is allowed to be placed into the accommodation space 10 through the opening 11 by the action of sliding component 39. After the rear end 33 of the chassis unit 30 is placed into the accommodation space 10 through the opening 11, a tail end of the slide rail structure 31 is moved toward the positioning roller 20. Since the positioning roller 20 has the axis C parallel to the second direction (i.e., parallel to the Z axial direction), when the slide rail structure 31 is moved relative to the positioning roller 20 along the first direction (i.e., parallel the X axial direction), the positioning roller 20 can roll relative to the slide rail structure 31 to achieve both labor-saving and position-limiting functions at the same time. Thereby, the chassis unit 30 can be smoothly inserted into or removed from the accommodation space 10 on the chassis device 9, to avoid the collision damage or the scratches on the lateral wall of the chassis unit 30 and the inner wall of the accommodation space 10.

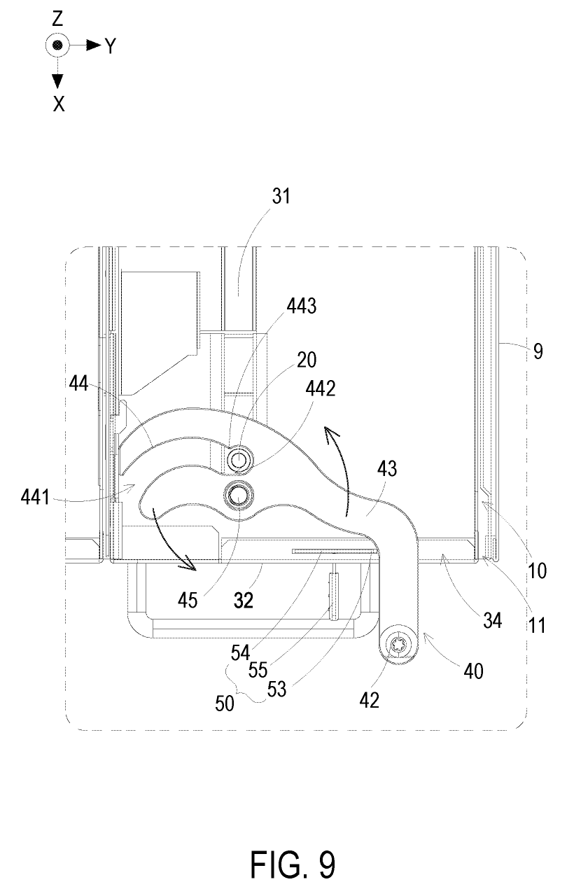

In the embodiment, the handle component 40 includes two hook structures 41 arranged in pairs. The two hook structures 41 are spatially corresponding to the slide rail structures 31 of the chassis unit 30 arranged in pairs and the positioning rollers 20 on the top 12a and the bottom 12b of the accommodation space 10. In the following descriptions, only one single hook structure 41 corresponding to one single slide rail structure 31 and one single positioning roller 20 is taken as an example, and the present disclosure is not limited thereto. As shown in FIGS. 7-9, in the embodiment, the hook structure 41 includes an arc-shaped engagement groove 44, aligned to the slide rail structure 31 and the positioning roller 20. Moreover, when the handle component 40 is engaged with the positioning roller 20 through the arc-shaped engagement groove 44, the handle component 40 is driven to swing to the second position. In the embodiment, when the slide rail structure 31 is moved relative to the positioning roller 20 along the first direction (i.e., parallel to the X axial direction), the handle component 40 is pre-rotated to the first position (as shown in FIG. 7), and the positioning roller 20 allows being aligned to the tail end of the slide rail structure 31 and an open end 441 of the arc-shaped engagement groove 44. When the tail end of the slide rail structure 31 is close to the positioning roller 20, the handle component 40 is engaged with the positioning roller 20 through the arc-shaped engagement groove 44, and the handle component 40 is driven to rotate, as shown in FIG. 8. The arc-shaped engagement groove 44 is engaged with the positioning roller 20 until the positioning roller 20 is limited to the tail end of the slide rail structure 31 and engaged with the tail end 442 of the arc-shaped engagement groove 44, and the handle component 40 is driven to rotate to the second position (as shown in FIG. 9).

In the embodiment, the handle component 40 further includes a holding portion 42 and a connection rod 43. The hook structure 41 and the holding portion 42 are respectively located at two opposite ends of the connection rod 43. The hook structure 41 is located in the chassis unit 30, the holding portion 42 protrudes outwardly from the front end 32 of the chassis unit 30, and the connection rod 43 is pivotally connected to the chassis unit 30. In the embodiment, when the handle component 40 is swung to the first position (as shown in FIG. 7), the chassis unit 30 allows displacement along the first direction (i.e., parallel to the X axial direction), and the hook structure 41 allows engagement with the positioning roller 20 to drive the handle component 40 to swing to the second position (as shown in FIG. 9).

In the embodiment, when the handle component 40 is rotated to the second position, the positioning roller 20 is limited to the tail end of the slide rail structure 31 and engaged with the tail end 442 of the arc-shaped engagement groove 44. Thereby, the chassis unit 30 is locked in the accommodation space 10, and the holding portion 42 of the handle component 40 is retracted to the front end 32 of the chassis unit 30. Furthermore, in the embodiment, when the holding portion 42 is forced to protrude from the front end 32 and the handle component 40 is driven to swing from the second position to the first position, the positioning roller 20 is retained between the slide rail structure 31 and the open end 441 of the arc-shaped engagement groove 44, allowing the chassis unit 30 to move out of the accommodation space 10 through the opening 11. In other words, when the handle component 40 is swung, the arc-shaped engagement groove 44 and the slide rail structure 31 are at least partially intersect in the second direction (i.e., parallel to the Z axial direction), and the intersected place can be used for receiving the positioning roller 20 to be limited therein.

In the embodiment, the arc-shaped engagement groove 44 has a width W greater than a diameter D of the positioning roller 20, and is tapered from the opening end 441 to the tail end 442, as shown in FIG. 7. When the handle component 4 is rotated from the first position to the second position, the engagement of the handle component 40 and the positioning roller 20 is maintained through the arc-shaped engagement groove 44, as shown in FIG. 8. In the embodiment, the arc-shaped engagement groove 44 further includes a clamping point 443 disposed on the tail end 442 of the arc-shaped engagement groove 44. When the chassis unit 30 is completely accommodated in the accommodation space 10, the clamping point 443 is engaged with the positioning roller 20, to ensure that the chassis unit 30 is correctly accommodated in the accommodation space 10.

In the embodiment, the slide roller structure 31 is in communication along the first direction (i.e., parallel to the X axial direction) from the rear end 33 toward the front end 32 of the chassis unit 30, but does not run through the front end 32. In the embodiment, the handle component 40 is disposed on the chassis unit 30 through a pivot component 45 such as a ball bearing. The pivot component 45 is located between the tail end of the slide roller structure 31 and the front end 32 of the chassis unit 30.

Please refer to FIGS. 1 and 2. In the embodiment, the chassis unit 30 includes a window 34 disposed on the front end 32 of the chassis unit 30 and extended along the third direction (i.e., parallel to the Y axial direction). In the embodiment, the hook structure 41 is located in the chassis unit 30, and the connection rod 43 passes through the windows 34 on the top 35 and the bottom 36 from the front end 32 of the chassis unit 30. Moreover, when the handle component 40 is swung between the first position and the second position, the connection rod 43 is swung between two opposite ends of the window 34. The holding portion 42 is connected along the second direction (i.e., the Z axial direction) to facilitate the user to apply force for operation.

FIGS. 10-13 illustrate the detailed structure of the latching component 50. In the embodiment, the latching component 50 includes a fixing bracket 51, an elastic element 52 and a latch element 53. Preferably but not exclusively, the fixing bracket 51 is disposed on the front end 32 of the chassis unit 30 and arranged adjacent to the holding portion 42 unfolded at the second position (as shown in FIG. 9). The latch element 53 is connected to the fixing bracket 51 through the elastic element 52. In the embodiment, the latch element 53 is allowed to protrude into the window 34. When the latch element 53 protrudes into the window 34, the handle component 40 is locked at the second position (as shown in FIG. 9).

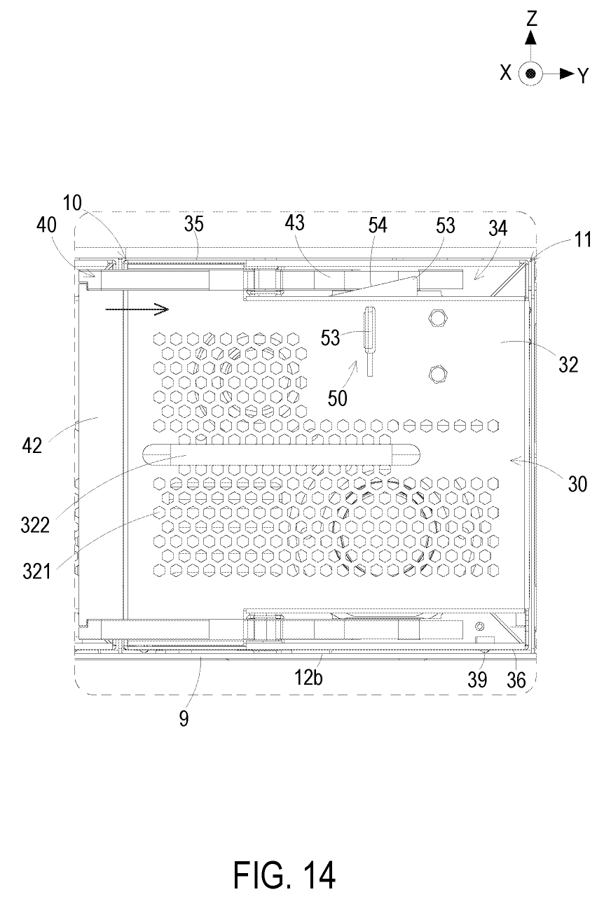

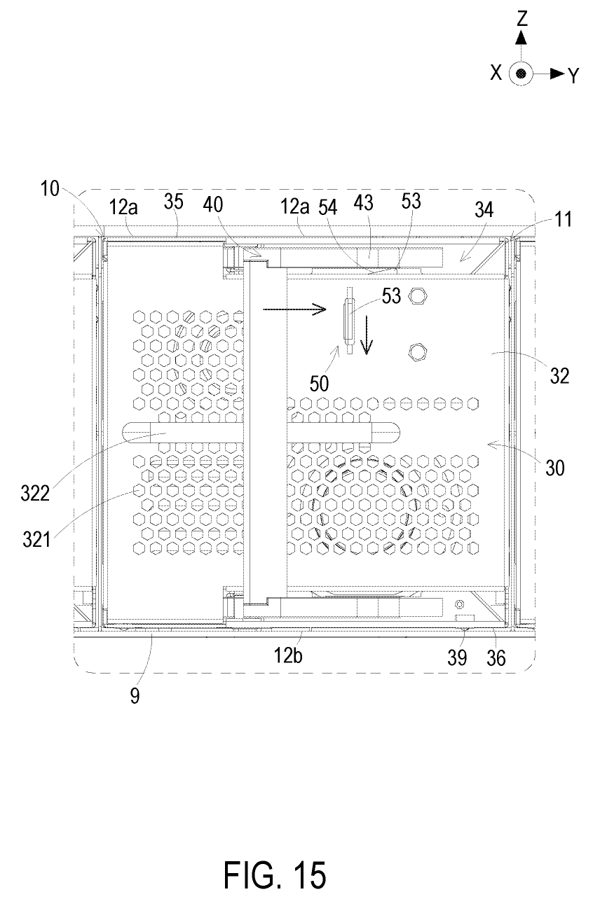

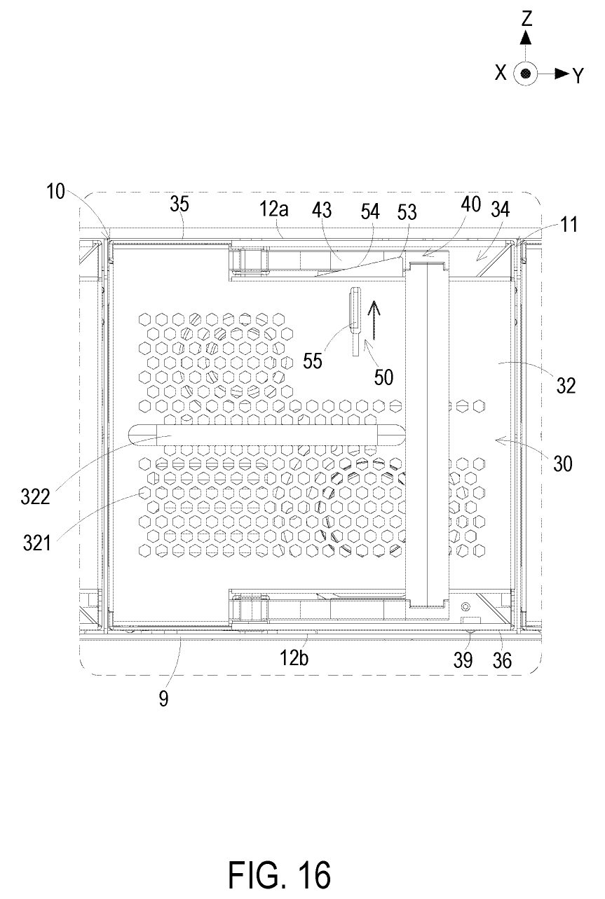

In the embodiment, FIGS. 14-16 illustrate the process of swinging the handle component 40 from the first position to the second position and activating the latching component 50 to restrict the handle component 40 at the second position. FIG. 14 is a front view illustrating the handle component swung to the first position. FIG. 15 is a front view illustrating a transition state of the handle component being swung from the first position to the second position. FIG. 16 is a front view illustrating the handle component swung to the second position. Please refer to FIGS. 1-16. In the embodiment, the latch element 53 further includes an inclined surface 54, and a height of inclined surface 54 is increased from the first position to the second position, that is, increased along the Y axial direction. When the holding portion 42 is subjected to force to swing the handle component 40 from the first position to the second position, the connection rod 43 pushes against the inclined surface 54, and further pushes against the elastic element 52 through the inclined surface 54, so that the latch element 53 is driven to disengage from the window 34. When the handle component 40 is swung to the second position, the connection rod 43 is disengaged from the inclined surface 54 to release the elastic element 52, and the latch element 53 protrudes to the window 34 to lock the handle component 40 at the second position (as shown in FIG. 16). In the embodiment, the inclined surface 54 has an inclination angle A ranged from 10 degrees to 45 degrees. In case of that the inclination angle A is larger, the connection rod 43 must provide greater force to resist the elastic force of the elastic element 52 when the handle component 40 is swung, but the inclined surface 54 occupies a shorter distance in the window 34. In case of that the inclination angle A is smaller, the connection rod 43 can drive the latch element 53 more smoothly when the handle component 40 is swung, but the inclined surface 54 needs to occupy a longer distance in the window 34. Preferably but not exclusively, the inclination angle A is ranged from 10 degrees to 15 degrees, and it is particularly conducive to optimal operation. In the embodiment, the chassis unit 30 further includes a plurality ventilation holes 321 and a fixed handle 322 disposed on the front end 32 of the chassis unit 30, but the operations of the handle component 40 and the latching component 50 are not affected.

Furthermore, if the latching component 50 needs to be released from the limit of the handle component 40, the latch element 53 needs to be subjected to force and push against the elastic element 52 and drive the latch element 53 to disengage from the window 34. In that, the handle component 40 is allowed to swing from the second position to the first position under the force of the holding portion 42. In other words, the latch element 53 of the latching component 50 is constantly pressed by the elastic element 52 to protrude into the window 34. When the latch element 53 is forced by for example but not limited to the pressing plate 55 to press against the elastic element 52 and disengage from the window 34, a misalignment of the latching component 50 and the connection rod 43 is maintained. At this time, the handle component 40 is allowed to swing between the first position and the second position.

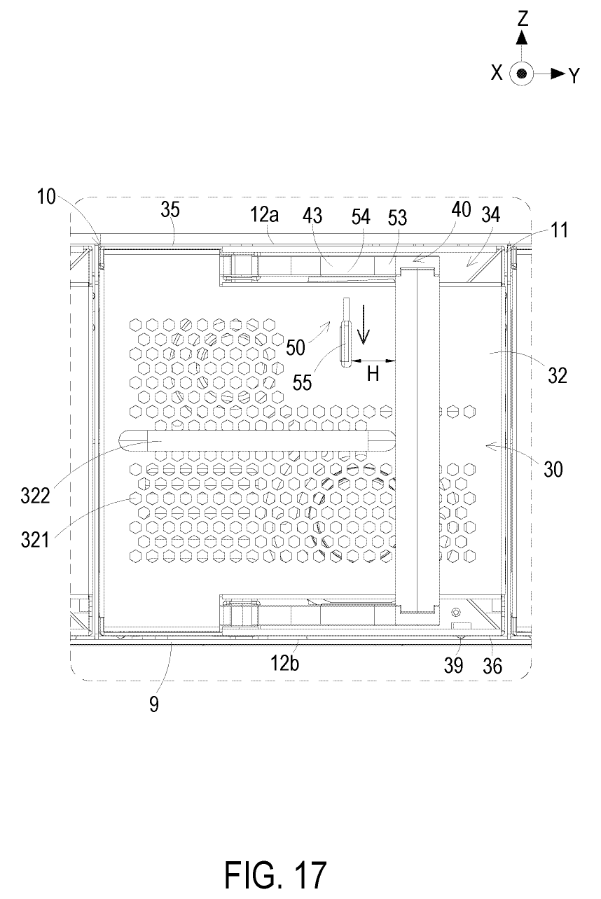

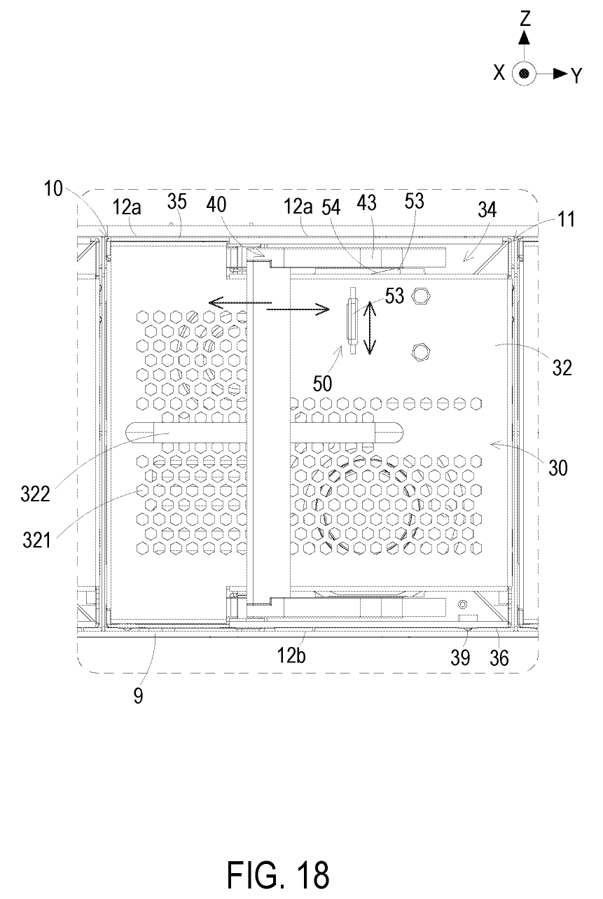

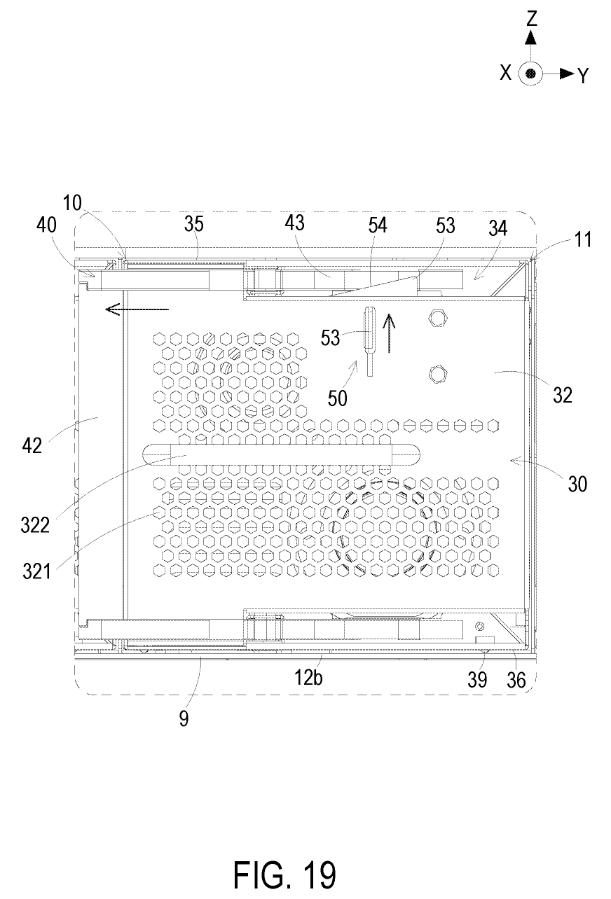

In the embodiment, FIGS. 17-19 illustrate the process of swinging the handle component 40 from the second position to the first position after the latching component 50 is unlocked. FIG. 17 is a front view illustrating the handle component swung to the second position and the latching component unlocked. FIG. 18 is a front view illustrating a transition state of the handle component being swung from the second position to the first position. FIG. 19 is a front view illustrating the handle component swung to the first position. Please refer to FIGS. 1-13 and 17-19. In the embodiment, the latch element 53 further includes a pressing plate 55. The pressing plate 55 protrudes from the front end 32 of the chassis unit 30, and is configured to receive force to drive the latch element 53 to press against the elastic element 52 and disengage the latch element 53 from the window 34. When the user wants to operate the handle component 40 to move the chassis unit 30 out of the accommodation space 10, the user must first release the handle component 40 from the restriction of the latching component 50. In the embodiment, the pressing plate 55 is separated from the holding portion 42 folded at the second position to form an operating distance H (as shown in FIG. 17), and the operating distance H is ranged from 3 cm to 6 cm, so that a user is allowed to simultaneously hold the holding portion 42 and move the pressing plate 55 with one hand. When the latching component 50 is out of the swing path of the handle component 40, the handle component 40 is allowed to swing to the unfold, i.e., the first position, and the chassis unit 30 is moved out of the accommodation space 10.

Notably, in the embodiment, the chassis unit 30 is, for example, a water pump module and includes a quick-connect joint 37 arranged at the rear end 33 of the chassis unit 30. When the chassis unit 30 is completely accommodated in the accommodation space 10, the quick-connect joint 37 is connected to a server water cooling system 13, as shown in FIG. 3. Certainly, the chassis unit 30 further includes other power or signal adapters 38 to achieve a hot-swappable connection with the system of the chassis device 9 when the chassis unit 30 is completely accommodated in the accommodation space 10. Preferably but not exclusively, the chassis unit 30 is detached when the chassis unit 30 is moved out of the accommodation space 10. Certainly, the chassis unit 30 can be a power supply unit or a data processing unit for a server room. The present disclosure is not limited thereto and not redundantly described hereafter.

In summary, the present disclosure provides a chassis device for a server room. By arranging a latching component on the swing path of a handle component, when the hook structure of the handle component is cooperated with a slide rail structure to engage with a positioning roller, the latching component is simultaneously activated by the handle component to limit the handle component at a fixed position, thereby fixing the chassis unit in an accommodation space, avoiding the risk of the chassis unit being separated from the system due to accidental human touch. Bearing balls are used to construct sliding components between the bottom of the accommodation space and the chassis unit to provide sufficient support and achieve labor-saving functions. In addition, the positioning roller includes the roller disposed on the top and bottom of the accommodation space and cooperated with a guiding groove disposed in the chassis unit to achieve both labor-saving and position-limiting functions. It allows the chassis unit being smoothly inserted into or removed from the accommodation space on the chassis device to avoid the collision damage or the scratches on the inner wall of the accommodation space. Notably, the handle component is pivotally connected to the front end of the chassis unit and further cooperated with the positioning component when the chassis unit is placed or moved out of the accommodation space. By meshing the arc-shaped engagement groove with the positioning component located in the guiding groove, the handle component is driven to fold or unfold the holding portion. It is convenient for users to operate and achieves labor-saving performance. Furthermore, a latching component with an inclined surface is arranged on the swing path of the handle component when it is folded or unfolded. The direction in which the handle component swings left and right is perpendicular to the direction in which the latching component stretches up and down. When the user operates the handle component to place the chassis unit into the accommodation space, the arc-shaped engagement groove and the positioning roller are engaged with each other to drive the handle component to swing. The handle component is swung first to push against the lower part of the inclined surface, and then the latching component is pressed out of the swing path of the handle component. When the chassis unit is completely accommodated in the accommodation space, the handle component is folded at a fixed position and the latching component is released, so that the latching component is reset to the swing path of the handle component, the swing of the latching component is limited, and the locking purpose is achieved. On the other hand, when the user wants to operate the handle component to move the chassis unit out of the accommodation space, the user can use one hand to move the latching component adjacent to the handle component, so that the latching component is pressed out of the swing path of the handle component. Then, the handle component is allowed to swing to the unfold position, thereby moving the chassis unit out of the accommodation space. Thereby, it allows the users to easily install or remove the chassis unit, and the entire process is smooth and effortless. Furthermore, without moving the latching component by hand, the handle component is swung and folded to activate the latching component, so that the handle component is limited to the folded position, thereby fixing the chassis unit in the accommodation space, avoiding the risk of the chassis unit being separated from the system due to accidental human touch.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A chassis device for a server room, comprising:
an accommodation space, comprising an opening, wherein the opening faces a first direction;
a positioning roller, disposed on a bottom and/or a top of the accommodation space, arranged adjacent to the opening, and having an axis parallel to a second direction;
a chassis unit, comprising a slide rail structure disposed on a bottom or/and a top of the chassis unit, wherein the slide rail structure is spatially corresponding to the positioning roller, allowing the chassis unit to be placed into or moved out of the accommodation space along the first direction through the opening;
a handle component, pivotally mounted on a front end of the chassis unit and comprising a hook structure spatially corresponding to the positioning roller and the slide rail structure, wherein the handle component is allowed to swing in a third direction relative to the front end, and the first direction, the second direction and the third direction are perpendicular to each other; and
a latching component, disposed on the front end of the chassis unit and spatially corresponding to the handle component, wherein the slide rail structure is aligned with the positioning roller to allow the chassis unit to slide into the accommodation space, wherein when the handle component is swung along the third direction and the hook structure is engaged with the positioning roller, the latching component is activated to limit the handle component from swinging.

2. The chassis device for the server room according to claim 1, wherein the handle component further comprises a holding portion and a connection rod, the hook structure and the holding portion are respectively located at two opposite ends of the connection rod, the holding portion protrudes outwardly from the front end, and the connection rod is pivotally connected to the chassis unit, wherein the handle component is swung to a first position, the chassis unit allows displacement along the first direction, and the hook structure allows engagement with the positioning roller to drive the handle component to swing to a second position.

3. The chassis device for the server room according to claim 2, wherein the chassis unit comprises a window disposed on the front end of the chassis unit and extended along the third direction, and the connection rod passes through the window, wherein when the handle component is swung between the first position and the second position, the connection rod is swung between two opposite ends of the window.

4. The chassis device for the server room according to claim 3, wherein the latching component comprises a fixing bracket, an elastic element and a latch element, the fixing bracket is disposed on the front end of the chassis unit and arranged adjacent to the holding portion unfolded at the second position, and the latch element is connected to the fixing bracket through the elastic element, wherein the latch element is allowed to protrude into the window, wherein when the latch element protrudes into the window, the handle component is locked at the second position.

5. The chassis device for the server room according to claim 4, wherein the latch element further comprises an inclined surface, and a height of the inclined surface is increased from the first position to the second position, wherein when the holding portion is subjected to force to swing the handle component from the first position to the second position, the connection rod pushes against the elastic element through the inclined surface, so that the latch element is driven to disengage from the window, wherein when the handle component is swung to the second position, the connection rod is disengaged from the inclined surface to release the elastic element, and the latch element protrudes to the window to lock the handle component at the second position, wherein the latch element is subjected to force to push against the elastic element and drive the latch element to disengage from the window, the handle component is allowed to swing from the second position to the first position under the force of the holding portion.

6. The chassis device for the server room according to claim 5, wherein the inclined surface has an inclination angle ranged from 10 degrees to 45 degrees.

7. The chassis device for the server room according to claim 5, wherein the latch element further comprises a pressing plate protruding from the front end of the chassis unit and configured to receive force to drive the latch element to press against the elastic element and disengage the latch element from the window.

8. The chassis device for the server room according to claim 7, wherein the pressing plate is separated from the holding portion folded at the second position to form an operating distance, and the operating distance is ranged from 3 cm to 6 cm, so that a user is allowed to simultaneously hold the holding portion and move the pressing plate with one hand.

9. The chassis device for the server room according to claim 7, wherein the latch element is constantly pressed by the elastic element to protrude into the window, wherein when the latch element is forced by the pressing plate to press against the elastic element and disengage from the window to maintain a misalignment with the connection rod, the handle component is allowed to swing between the first position and the second position.

10. The chassis device for the server room according to claim 3, wherein the hook structure is received within the chassis unit, the connection rod is connected between the hook structure and the holding portion, and protrudes from the front end of the chassis unit through the window, and the holding portion is located outside the front end of the chassis unit.

11. The chassis device for the server room according to claim 2, wherein the hook structure comprises an arc-shaped engagement groove for being aligned with the slide rail structure and the positioning roller, and the arc-shaped engagement groove is allowed engaging the positioning roller and driving the handle component to swing to the second position.

12. The chassis device for the server room according to claim 11, wherein when the handle component is swung to the second position, the positioning roller is limited to a tail end of the slide rail structure and engaged with a tail end of the arc-shaped engagement groove, the chassis unit is locked in the accommodation space, the holding portion is retracted to the front end of the chassis unit, and the holding portion is locked at the second position through the latching component.

13. The chassis device for the server room according to claim 12, wherein when the holding portion is forced to protrude from the front end and drive the handle component to swing from the second position to the first position, the positioning roller is limited to the slide rail structure and an opening end of the arc-shaped engagement groove, and the chassis unit allows being moved out of the accommodation space through the opening.

14. The chassis device for the server room according to claim 11, wherein when a tail end of the slide rail structure is close to the positioning roller, the handle component is engaged with the positioning roller through the arc-shaped engagement groove, and the handle component is driven to rotate to the second position.

15. The chassis device for the server room according to claim 11, wherein the arc-shaped engagement groove has a width greater than a diameter of the positioning roller, and is tapered from an opening end to a tail end, and the arc-shaped engagement groove further comprises a clamping point disposed on the tail end of the arc-shaped engagement groove, wherein when the chassis unit is completely accommodated in the accommodation space, the clamping point is engaged with the positioning roller.

16. The chassis device for the server room according to claim 11, wherein when the handle component is swung, the arc-shaped engagement groove and the slide rail structure are at least partially intersected.

17. The chassis device for the server room according to claim 2, wherein the slide rail structure is in communication along the first direction from a rear end of the chassis unit toward the front end, wherein when the rear end of the chassis unit is placed into the accommodation space through the opening, the handle component is pre-rotated to the first position, and the positioning roller allows being aligned to a tail end of the slide rail structure.

18. The chassis device for the server room according to claim 1, wherein the handle component is disposed on the chassis unit through a pivot component, and the pivot component is located between a tail end of the slide rail structure and the front end of the chassis unit.

19. The chassis device for the server room according to claim 1, wherein the chassis unit is a water pump module and comprises a quick-connect joint arranged at a rear end of the chassis unit, wherein when the chassis unit is completely accommodated in the accommodation space, the quick-connect joint is connected to a server water cooling system.

20. The chassis device for the server room according to claim 1, wherein the chassis unit further comprises a sliding component, and the sliding component is arranged at a bottom of the chassis unit along the first direction, wherein the sliding component allows the chassis unit to slide relative to the accommodation space along the first direction therethrough and supports the chassis unit.
